(19) United States
(12) Patent Application Publication
(10) Pub. No.: US 2026/0120928 A1
(43) Pub. Date: Apr. 30, 2026

(54) REINFORCED HIGH TEMPERATURE SUPERCONDUCTOR SOLENOIDS

(71) Applicant: LAU Superconductors Inc., Hunt Valley, MD (US)

(72) Inventor: Wayne Chung Wei Lau, Geneva (CH)

(21) Appl. No.: 18/917,901

(22) Filed: Oct. 16, 2024

Related U.S. Application Data
(60) Provisional application No. 63/544,819, filed on Oct. 19, 2023.

(51) Int. Cl. H01F 6/00; H01F 41/04

(52) U.S. Cl. CPC H01F 6/00; H01F 41/048

(57) ABSTRACT

1. A single HTS crystal block is created by: adding HTS constituent materials into a mold to create a material layer, where the layer includes a material plane; disposing fibers that extend approximately from one edge to another edge of the mold on the material plane to create a fiber layer; adding other HTS constituent materials into the mold on top of the fiber layer to create an other material layer; compressing the material layer, the fiber layer, and the other layer in the mold to create a compressed reinforced HTS material block; removing the compressed reinforced HTS material block from the mold; heating the compressed reinforced HTS material block with the material block flat surface being in contact with a flat surface of a single crystal seed plate; and cooling the HTS material block to create the single HTS crystal block.

### CROSS REFERENCE TO OTHER APPLICATIONS

This application claims priority to U.S. Provisional Patent Application No. 63/544,819 entitled VARIOUS INNOVATIONS FOR REINFORCED HIGH TEMPERATURE SUPERCONDUCTORS filed Oct. 19, 2023 which is incorporated herein by reference for all purposes.

### BACKGROUND OF THE INVENTION

The first high-temperature superconductor (HTS) was discovered in 1986. Its discoverers were immediately awarded the 1987 Nobel Prize in Physics partly because of expectations for rapid application. Superconductivity is the property of transmitting electricity with no or little resistance. In theory, superconducting materials can also create unlimitedly large magnetic fields

The HTS break-through was the discovery of superconductivity in ceramic materials. Previously superconductivity was seen only in metallic superconductors which needed to be cooled below 30 K (−243.2° C.) to achieve superconductivity. Such temperatures could in practice be obtained using liquid helium or liquid hydrogen which are expensive to use, increasingly rare in the case of helium, and/or dangerously explosive in the case of hydrogen. In contrast, HTS can achieve superconductivity at temperatures as high as 138 K (−135° C.) and can be cooled using substances such as liquid nitrogen, which is commercially widely available, stable, and inexpensive. Unfortunately, after nearly four decades of intense experimental and theoretical research, with over 100,000 published papers on the subject and numerous early patents (nearly all expired), no widely accepted theory explains the properties of HTS materials, and no significant HTS applications have been found to be practical.

This reflects four problems: 1) unlike metals which are commonly used to transmit electricity, HTS ceramics are brittle making them expensive to manufacture and difficult to form into wires and other useful shapes; 2) highest performing HTSs are single crystals (bulk) superconductors where the entire sample is a single molecular lattice where superconductivity fails with the slightest lattice crack, 3) HTS does not form large, continuous superconducting domains, but clusters of micro-domains within which superconductivity occurs; and 4) the HTS production process is complicated requiring a multiple calcination of ingredients at high temperatures ranging from 800° C. to 950° C. for several hours following sintering, which is done at 950° C. in an oxygen atmosphere where oxygen stoichiometry is very crucial for obtaining the superconducting compound. Slow cooling in an oxygen atmosphere turns the material superconductive involving both the uptake and loss of oxygen.

The complex role of oxygen in production prohibits the use of most reinforcing materials to relieve the brittleness and cracking described above. This is because nearly all potential materials, which are stable across this process' high temperature such as metals, carbon, composites, ceramics, etc., oxidize during this process, which interferes with the creation of the HTS material. The oxidation either creates impurities or depletes oxygen at critical times in the production process and crystal formation.

Current attempts to find useful HTS materials focus on external reinforcement such as packing-in-tube (PIT) wire production, encasing HTS in durable materials like stainless steel, or additive processes such as attempting to apply HTS as a coating on film or tape.substrates (Coated). Both PIT and external encasing are difficult to produce economically in shapes and constructions for practical applications. Coated techniques which attempt to grow HTS on reinforcement substrates have limited commercial use and, to date, have not produced significantly robust HTS components for most applications. For example, attempts have been made to use HTS in electrical applications such as Superconductor Fault Current Limiters (SFCL), Superconductor Magnetic Energy Storage (SMES), transformers, and transmission cables where strength is not critical. But these have not yet resulted in widespread HTS for technical and economic reasons.

Attempts have been made to internally reinforce HTS using discontinuous fibers (also known as chopped fibers) and particles. These have generally failed due to a) contamination during production and/or b) agglomeration of the discontinuous particles/fibers during the melt phase of production. For agglomeration, sintering powders are melted into liquid form. When in liquid, discontinuous pieces move and stick together (agglomerate) forming masses which disrupt crystal formation. These agglomerations create cracks and fault planes which reduce the strength of and disintegrate the final HTS crystal. This also causes discontinuous fibers and particles to react with HTS components during HTS formation possibly contaminating the process.

The most widespread superconductor application is for superconductor solenoids to generate large magnetic fields. Unreinforced HTS is too brittle to shape into wires which can be wound into solenoids. Attempts have been made externally to reinforce HTS by deposition of thin HTS crystal layers on tape substrates or packing HTS component powders in thin tubes which are compressed then heated to form HTS crystal. The conductors are then wound or preformed into solenoid shapes. These externally reinforced HTS are not yet widely used because the resulting conductor is very thin and difficult to produce consistently.

Superconductors often experience radial stress in magnetic applications. These stresses cause circumferential hoop strains which can lead to cracking. High Temperature Superconductors being single crystals are especially sensitive to fractures resulting in failure. High Temperature Superconductors reinforced with continuous fiber (Reinforced HTS) can be strengthened to resist these stresses and strains. However, the most efficient reinforcement fiber geometry against radial stress would be hoops or spiral fiber in circular form. Such circular fiber is not available widely.

High Temperature Superconductors are most commonly made using Top Seeded Melt Growth (TSMG). TSMG involves placing a small single seed crystal on top of compressed component powders which are melted then cooled for crystallization. The small seed crystal initiates single crystal growth at the point where it touches the top surface of the compressed powder. Unfortunately this creates a crystal growth front which is rounded, not flat. It is extremely difficult to lay reinforcement fiber in a complex rounded shape such that the crystal growth front reaches a group of fibers at the same time. Contact with some fibers before others may cause distortions in the crystal growth front which cause further distortions when reaching more fibers. Eventually single crystal growth can be disrupted causing multi-crystal growth which disrupts superconductivity.

### BRIEF DESCRIPTION OF THE DRAWINGS

Various embodiments of the invention are disclosed in the following detailed description and the accompanying drawings.

FIG. 1A is a diagram illustrating an embodiment of a process for a reinforced HTS material.

FIG. 1B is a diagram illustrating an embodiment of a cross section of a reinforced HTS material.

FIG. 1C is a diagram illustrating an embodiment of a cross section of a reinforced HTS material.

FIGS. 2A-2L are block diagrams illustrating an embodiment of a process for a reinforced HTS material.

FIG. 3 is a diagram illustrating an embodiment of a reinforced HTS material.

FIG. 4 is a diagram illustrating an embodiment of fibers of a set of fibers for reinforcement of an HTS material.

FIG. 5 are diagrams illustrating a process for a reinforced HTS solenoids.

FIG. 6 are diagrams illustrating a process for a reinforced HTS solenoids.

FIG. 7 is a flow diagram illustrating an embodiment of a process for a reinforced HTS material.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

A reinforced superconducting composition comprises one or more continuous fibers that is/are embedded in a high temperature superconducting (HTS) material. The fibers are of sufficiently long length or sufficiently large aspect ratio (the ratio of fiber length to width) such that the fibers do not migrate, agglomerate, nor react sufficiently during HTS sintering and crystallization to weaken the final HTS material below that of unreinforced HTS. Fibers can be connected together in structures so that they do not migrate, agglomerate nor react sufficiently during HTS sintering and crystallization to weaken the final HTS material below that of unreinforced HTS. In some embodiments, the fibers are long in the event that the fibers span the HTS from one edge to another. In various embodiments, the fibers are 3, 4, 5, 6, 7, 8, 9, 10, 20, 30, 50 mm long, or any other appropriate length. In some embodiments, the fibers are composed of multiple filaments and/or non-continuous strands which may or may not be composed as threads and/or braids.

In some embodiments, the one or more continuous fibers is/are comprised of an element which a) has a high melting point and b) forms a very durable oxide form that prevents contamination of a high temperature superconducting material. In some embodiments, the one or more continuous fibers comprise SiC fiber. In various embodiments, the one or more fibers comprise Silicon (Si), Silicon Nitride (Si₃N₄), Silicates including Silicon Dioxide (SiO₂), Boron (B), Boron Carbide (B₄C), Boron Nitride (BN), Chromium (Cr), Chromium Carbides (Cr₃C₂, Cr₇C₃, Cr₂₃C₆), Chromium Nitrides (CrN, Cr₂N), Hafnium Carbide (HfC), Zirconium Carbide (ZrC), Zirconium Nitride (ZrN), Zirconium Diboride (ZrB₂), Titanium (Ti), Titanium Carbide (TiC), Titanium nitride (TiN), Tungsten Carbide (WC), Aluminum (Al), Alumina (Al₂O₃), Aluminum Carbide (Al₄C₃), Aluminum Nitride (AlN), Titanium Aluminum Nitride (TiAlN), Aluminum Titanium Nitride (AlTiN), or any other appropriate material. These materials are referred to herein as Reinforcing Materials.

A reinforced high temperature superconducting material is disclosed. The high temperature superconducting material has zero electrical resistance at a temperature above 25° K. In various embodiments, the high temperature superconducting material comprises one or more of the following: a ceramic material, a copper oxide material, a rare earth copper oxide material (RE)BCO (e.g., (RE)Ba₂Cu₃O₇), an iron arsenide material, an iron selenide material, a LaBaCuO material, a LaSrCuO material, a LaSrCaCuO material, a YBaCuO material, a BiSrCaCuO material, a TiBaCaCuO material, a HgBACaCuO material, a HgTiBaCaCuO material, a LnFeAs(O,F) material, a (Ba, K, Li, Na)FeAs material, a FeSe material, a MgB material, a BKBO material, a RbCsC material, a YbPdBC material, a NbGe material, or any other appropriate material. Note that RE stands for a rare earth element, where the rare earth elements include cerium (Ce), dysprosium (Dy), erbium (Er), europium (Eu), gadolinium (Gd), holmium (Ho), lanthanum (La), lutetium (Lu), neodymium (Nd), praseodymium (Pr), promethium (Pm), samarium (Sm), scandium (Sc), terbium (Tb), thulium (Tm), ytterbium (Yb), and yttrium (Y). These materials are typically made by heating the component powders in the appropriate proportions until they anneal and then cooling until a crystal is formed. These materials are referred to herein as High Temperature Superconductors or HTS.

The one or more continuous fibers are arranged in an array. In various embodiments, the array comprises one of the following: a one dimensional array, a two dimensional array, a three dimensional array, or any other appropriate array. In some embodiments, the two or more continuous fibers are connected or coupled to each other. In some embodiments, the two or more continuous fibers are not connected nor coupled to each other. In various embodiments, the one or more fibers are arranged in parallel lines, in parallel curves, or any other appropriate reinforcement arrangement.

In various embodiments, the high temperature superconductive material is shaped using subtractive cutting, is shaped using cutting and dividing, or any other process for creating a shape. In various embodiments, the high temperature superconductive material is produced using a batch process, a continuous process, or any other appropriate process.

In some embodiments, the one or more fibers are pre-stressed during manufacturing (e.g., put under mechanical tension—for example, by pulling on the ends of the fiber). In various embodiments, the one or more fibers are used for cooling the high temperature superconducting material, are used to heat the high temperature superconducting material, are used to transmit electrical signals into the high temperature superconducting material, or any other appropriate use within the high temperature superconducting material. In some embodiments, the fiber comprises a composite fiber, where the components of the fiber are selected to enhance or be compatible with the property desired (e.g., cooling, heating, and/or transmitting electricity, etc.).

Continuous, long fiber is used for physical internal reinforcement of an HTS material to prevent contamination during crystal formation and cracking of the final crystal which causes the superconductivity of HTS material to fail. Long continuous fiber is distributed through the HTS sintering components powder then processed with the HTS sample through a sintering, crystallization, and cooling process. The use of long continuous fiber prevents problems when fibers agglomerate and react causing weakness in HTS crystal. In some embodiments, discontinuous fibers of approximately 4 mm in length that are added to HTS component powders before sintering physically reinforce an HTS material and prevent contamination during crystal formation and cracking of the final HTS crystal. These agglomerations and reactions are especially acute during the melt phase of HTS crystal production. The length of long continuous fibers, especially when connected or held fixed, prevents the fibers from moving, clumping, and reacting unnecessarily to the detriment of HTS crystal formation. In some embodiments, the fibers are long in the event that the fibers span the HTS from one edge to another and/or just shy of or just beyond or way beyond the edge(s) of the HTS crystal. In various embodiments, the fibers are 3, 4, 5, 6, 7, 8, 9, 10, 20, 30, 50 mm long, or any other appropriate length to prevent agglomeration.

In some embodiments, carbon fiber (e.g., SiC fiber) and/or other fiber is a strong reinforcing material which is stable over the wide range of temperatures involved in sintering, crystallizing and processing bulk HTS crystal.

In some embodiments, although oxygen reacts readily with most materials, the specified fibers create a durable oxide layer that prevents contamination of a high temperature superconducting material. For example, SiC carbon fiber creates a durable layer of silicon dioxide (SiO₂) from a reaction of silicon Si with oxygen O during the initial heating of the HTS sintering, in which the component powders are melted into a liquid phase. This SiO₂ layer prohibits further reaction with oxygen during the remaining HTS production process. This process is similar to how aluminum (Al), which normally reacts readily with oxygen, forms a durable coat of aluminum oxide Al₂O₃, which prevents further reactions. The oxide layer allows aluminum to be used safely for foil, pots, and pans without the fear of either an explosive chemical reaction or aluminum poisoning (except in the case of highly acidic foods like rhubarb which can dissolve the Al₂O₃ coating during cooking).

In some embodiments, the use of continuous, long fiber permits the fiber to retain its position in the metal phase liquid and prevents the agglomeration seen with discontinuous fibers and particles, which ultimately weakens and disintegrates the HTS crystal.

In various embodiments, continuous, long fiber can be formed into a variety of simple reinforcement structures involving unconnected fibers such as single planes of one dimensional fiber arrays, two dimensional fiber arrays with alternating stacked layers of planes in orthogonal directions, full three dimensional unconnected arrays or lattices of fibers, or any other appropriate reinforcement arrangements.

By connecting continuous, long fiber, a variety of reinforcement structures like single and layered two dimensional nets as well as three dimensional connected mesh structures can be made. For example, these structures, nets, or meshes create an internal reinforcement similar to concrete reinforcement that strengthens the material by redistributing stresses and strains, which prevents cracking.

By using both linear and non-linear, unconnected and connected continuous long fiber, complex reinforcement structures can be formed for any desired geometry of HTS superconductor.

Fiber reinforcement will permit HTS components to be produced cheaply and with precision through the technique of Subtractive Sculpting (e.g., the removal of material to achieve a desired shape—for example, by cutting, carving, scraping, grinding, etc.). Until now attempts at producing usable HTS components exclusively focused on either creating thin single crystal films through two-dimensional deposition on substrates or bulk three-dimensional HTS crystals in molds or other fixed containers. These methods are expensive, restrict the shape and size of components, and require the custom manufacture of each component to exact specifications making it extremely difficult to physically modify a component after it is produced. Fiber reinforcement strengthens and reduces the brittleness of a bulk HTS allowing parts to be sculpted (i.e., carved, cut, ground or otherwise extracted away) from a block of HTS material without disrupting the superconductivity of the crystal lattice. Thus, an unlimited variety of HTS component geometries can be produced including wires, rods, spirals, films, tapes, plates, blocks, spheres and three dimensional complex forms for use in specific electric and magnetic applications. Subtractive Sculpting also allows more precise component manufacture by eliminating geometric uncertainties in thermal expansion/contraction as HTS crystallizes and cools during production. Cooling causes thermal expansion and contraction which is difficult to predict and varies greatly depending on an HTS crystal's internal cooling temperature gradients and shape. Production using molds and film deposition are prone to such thermal uncertainties since their external reinforcement cannot be easily modified once the HTS crystal has formed. The much greater manufacturing precision provided by Subtractive Sculpting due to fiber internal reinforcement will allow much less wastage of less-than-perfectly formed HTS components. The efficiency will substantially reduce the cost of fiber reinforced HTS components leading to more commercial applications.

Fiber reinforcement allows a single production block to be cut in to a large number and/or variety of different components. This increases production efficiency and reduces costs leading to more commercial applications.

Fiber reinforcement (e.g., SiC and/or other fiber reinforcement) will also make HTS and proto-HTS materials strong enough for Continuous HTS Production which will significantly reduce manufacturing cost leading to HTS use in more applications. Currently, HTS is produced in batches where single bulk crystals or films are first sintered/deposited then allowed to cool under controlled conditions to allow crystal growth. While suitable for research, batch production is inefficient and expensive requiring considerable labor for each batch and leaving most equipment unused during each production run. Continuous HTS Production is a multi-stage process where: 1) fiber reinforcement is placed within a continuous tube sheath or are formed into a shape by compression prior to or at the entrance to the continuous production line, 2) constituent HTS chemicals in sintering powder form are mixed and place with the fiber reinforcement in the tube or shape, 3) the HTS is then packed and heated to sintering temperatures as the tube or shape is moved through a processing oven machine, 4) the tube or shape then moves through a cooling process where a single long HTS crystal continuously forms, 5) once crystallized, the continuous HTS crystal tube or shape is cooled to room temperature, and 6) the HTS tube or shape is then cut at intervals to produce individual bulk single crystal HTS blocks. The individual blocks are then Subtractively Sculpted into individual components.

Continuous production requires that the single HTS crystal be strong enough to withstand the strains and stresses of continuous movement during production. This is done by placing fiber reinforcement with the sintering component powders in the continuous tube or shape before sintering. The reinforcement reduces the brittleness of and strengthens the HTS such that the continuous tube of HTS can be transported seamlessly through mixing, packing, sintering, cooling, and cutting without breaking the HTS' essential single crystal structure.

To further strengthen HTS components against brittleness and cracking, fibers can be pre-stressed during sintering and throughout HTS production with specialized processes, equipment, and control mechanisms. The physical principle behind pre-stressing is that a compressive force (F) within the HTS crystal is created by the continuous lateral force induced by the stressed fiber reinforcement. This compressive force increases the external forces (P) which the HTS crystal can bear before cracking.

Pre-stressing involves applying carefully controlled and monitored tension at ends of individual reinforcing fibers before sintering and cooling. After the HTC crystal forms around the fibers, the crystal matrix will hold the fiber and extend the fiber's force completely through the HTS such that tension on the external fiber ends will no longer be needed. External fiber ends can then be trimmed, and the now pre-stressed strengthened HTS can be divided, cut and subtractively shaped into final component shape.

For batch production, pre-stressing forces would be applied on the external fiber ends sticking out of the HTS before the HTS component powders are added to the reinforcement in the casing at the beginning of the process. At the end of the process after HTS crystal has been formed but before production blocks are cut, lateral tension is maintained by friction rollers in contact directly with the production casing covering the now solid HTS crystal. In various embodiments, the tension is achieved by grabbing, clamping, or holding the fiber end(s) and pulling, or any other appropriate means of creating tension. Pre-stressing tension is maintained as the component powders are added then continued during the sintering and cooling phases of HTS production. Once the HTS crystal is formed, the Pre-stressing tension is released pass the friction rollers. The HTS crystal matrix will now hold the pre-stressed fibers under force throughout the HTS thereby making it much stronger than without pre-stressing.

Continuously produced Reinforced HTS can be Radially Pre-stressed by placing fibers perpendicular or at an angle to the axis of the lateral movement of the production tube casing such that individual fiber ends protrude from the casing. The tube is then be filled with HTS component sintering powder. A pre-stressing jig is then assembled around the production casing which secures the ends and provides Pre-Stressing Tension to the radial fiber extruding from the casing. This jig keeps pre-stressing tension on the radial fibers as the HTS is sintered then crystallized and cooled. Once the HTS crystal is formed, the radial fibers are held at force by the crystal matrix. The pre-stressing jig is then disassembled and taken off the casing before the final pre-stressing tension rollers for Lateral Pre-Stressing described above.

The conductivity and magnetic fields of reinforced HTS components can be controlled by varying the temperature and/or electric current at the external fiber ends of the fibers. This is because both the electrical conductivity and thermal conductivity of fiber differs from HTS. By passing different levels of heat or electric current through different fibers, individual parts of a single HTS component can be subject to more or less heat/electric current than others. This will allow superconductivity to be “turned off” or “turned on” in precise parts of any given HTS component. In addition, the heat/current passed through can varied over time allowing dynamic control of micro-magnetic and micro-electric fields across the three spatial dimensions and the fourth dimension of time (i.e., 4D control of local HTS properties using a matrix of control lines that can spatially and temporally deposit or deprive heat, cooling, current, to a localized area in a HTS material).

In various embodiments, features of the reinforced HTS material include:
using continuous, long fiber silicon carbide fiber to reinforce HTS to prevent contamination during crystal formation and cracking of the HTS crystal;
using unconnected continuous, long fibers placed in arrays to reinforce and strengthen HTS; and
using connected continuous, long fibers placed in two and three dimensional reinforcement structures.

In various embodiments, reinforced HTS material are produced using:
Subtractive Sculpting, where HTS material is extracted through a sculptive process rather than the additive process of external molding and film/tape deposition which will increase production efficiency and reduce costs leading to more commercial applications;
Cutting and dividing single HTS blocks into a large number and/or variety of different components which will increase production efficiency and reduce costs leading to more commercial applications;
Continuously Producing HTS to significantly reduce production cost and time compared to current batch production;
Pre-stressing HTC during crystal formation in batch production to increase strength;
Pre-stressing HTC laterally during crystal formation in Continuous Production to increase HTS strength; and
Pre-stressing HTC radially during crystal formation in Continuous Production to increase HTS strength.

In some embodiments, reinforced HTS materials enable micro-control of electric and magnetic fields over three spatial dimensions as well as time (4D) by using a matrix of Reinforcement fibers to turn off and on individual parts of an HTS component by transmitting heat or electricity through the ends of Reinforcement fibers which extend beyond the HTS component. This will allow greater HTS use in the Electric Power industry for Superconductor Fault Current Limiters (SFCL), Superconductor Magnetic Energy Storage (SMES), Transmission Cables & Wires, Transformers, Generators/Motors, etc. where applications are challenged by Alternating Current (AC) Losses. AC Loss is a special phenomenon where alternating currents in HTS generate heat even when superconducting.

In some embodiments, reinforced HTS materials enable preventing the overheating of HTS by cooling the ends of the fiber Reinforcement fibers which extend beyond the HTS component to avoid the heating of HTS above superconducting temperatures. In some embodiments, the ends of the fiber reinforcement fibers are placed in a cooling bath and/or are configured in a radiator configuration to shed heat external to the HTS material.

In some embodiments, the systems include a processor, an interface, and a memory. In some embodiments, the systems further include a communications network (e.g., a wired network, a wireless network, or any appropriate combination of networks). The interface is configured to receive input from a user, one or more sensors (e.g., a temperature sensor, a strain sensor, an electric current sensor, a position sensor, a magnetic field sensor, a radiation sensor, a fluid flow sensor, etc.), a communications network, a computer system, a processor, or any other appropriate input. The interface is configured to provide output to a user, one or more devices (e.g., actuators, mechanical system, electrical system, switch, etc.), a communications network, a computer system, a processor, or any other appropriate output. The processor is configured to receive the input via the interface and to receive computer instructions as stored by the memory. The processor is further configured to determine appropriate output to provide based at least in part on the input received. In some embodiments, the processor is configured to provide instructions for controlling, sequencing, and/or manufacture of HTS composites including measuring process parameters (e.g., heating, timing, cooling, material inputs (e.g., composite powders, intermediate materials, fibers, magnetic particles, reinforcing sheaths, connecting materials, coating materials, cutting, separating, winding, etc.), or any other appropriate instructions. In some embodiments, the processor is configured to operate a device—for example a valve and/or actuator by providing opening instructions, closing instructions, armature position instructions, cooling instructions based in inputs including user inputs and sensor inputs. In some embodiments, aircraft subsystem instructions are provided to HTS valves and/or actuators including operating instructions (e.g., opening, closing, cooling, heating, etc.) with specific timing and/or sequencing based at least in part on user and/or sensor inputs. In some embodiments, nets or meshes in two or three dimensions and with 2 or 3 axes of symmetry are provided with instructions to maintain position, fold, turn on magnetic field generation, turn off magnetic field generation, or any other appropriate instruction based at least in part on user instructions or sensor (e.g., incoming radiation, etc.). In some embodiments, processor(s) provide instructions to tether components to stiffen, bend, compress, expand, to stabilize a tether based at least in part on sensor (e.g., position, strain, temperature, etc.) inputs. In some embodiments, a processor controls timing of a wave of magnetic field pulses to a water propulsion system based on user input speed instructions and/or fluid flow sensor readings. In some embodiments, a processor provides instructions to generate force by controlling magnetic field generation in a HTS solenoid tube and/or sabot in terms of amount, timing, etc.

Coated, Clad, and/or Composite Fiber for HTS Reinforcement

The Reinforcing Materials' main purpose is to prevent the contamination of HTS during sintering and crystallization. Coated, cladded, and/or composite HTS Reinforcing Fiber (e.g., a tungsten core with a SiC layer outside the core that forms a SiO₂ oxide), which is cheaper, stronger, and more flexible and which conducts heat and/or electricity better, can be made by placing Reinforcing Materials on cheaper, stronger, more flexible, more heat conductive and/or more electric current conductive long continuous substrate fiber. Substrates could also comprise special materials for specific purposes—for example, ferromagnetic material for Flux Pinning. Possible substrates could include, but are not limited to, materials with melting temperatures higher than the maximum sintering temperatures for HTS such as metals and metal alloys (e.g., Tungsten), ceramics, silicon based compounds (e.g., SiO₂), and/or carbon based compounds (e.g., graphene). In various embodiments, the materials comprise: Aluminum, Beryllium, Boron, Carbon, Chromium, Hafnium, Indium, Iridium, Iron, Molybdenum, Nickel, Niobium, Platinum, Rhenium, Rhodium, Silicon, Titanium, Tantalum, Titanium, Tungsten, Zirconium, and their alloys, compounds, and structures such as, but not limited to, Graphene, Silicon Oxides, Silicon Carbide, Zinc Aluminum Cadmium Alloy, Aluminum Magnesium Alloy, Nickel Aluminum Alloy, Beryllium Copper Alloy, Molybdenum Rhenium Alloy, Molybdenum Lanthanum Alloy, Tungsten Rhenium Alloy, Nickel Titanium, Tantalum Niobium Alloy, Tantalum Tungsten Alloy, or any other appropriate material. Coating, cladding, and/or forming composites can be done through vapor deposition (physical and chemical), chemical and electrochemical techniques, spraying, roll-to-roll coating, and/or other physical coating means.

The thickness of the Reinforcing Material coating, cladding and/or skin of the composite fiber should great enough such to provide the creation of the durable oxide layer with the Reinforcing Material that a) will prevent further oxidation with the HTS component powders during further sintering and HTS crystal production and b) leave enough original fiber material, whether Reinforcing Material or Substrate, to provide the physical properties desired from the reinforcing fiber. These physical properties include strength, connections with other fibers, structure, pliability and flexibility, as well as flux pinning properties including ferromagnetic infusions, etc. For example, with SiC Reinforcing Material, thicknesses below 1.5 um react too much during HTS formation. In some embodiments, a core fiber comprises a metal and a reinforcing material comprises SiC. In various embodiments, the core fiber is 5, 10, 15, 20, 30, 40, 50, 60, 70, 80, 90, 100, 150, 200, 300, 400, 500, 600, 700, 800, 900, 1000, 1500, 2000, 2500, 5000 nm, 500 um, 200 um, 100 um, 50 um, 40 um, 30 um, 20 um, 10 um, or any other appropriate in diameter. In various embodiments, the reinforcing material is 5, 10, 15, 20, 30, 40, 50, 60, 70, 80, 90, 100, 150, 200, 300, 400, 500, 600, 700, 800, 900, 1000, 1500, 2000, 2500, 5000, 10000, 50000, 100000 nm, or any other appropriate thickness around the core fiber. In various embodiments, the core fiber and the reinforcing material have a combined outer diameter of 10, 15, 20, 30, 40, 50, 60, 70, 80, 90, 100, 150, 200, 300, 400, 500, 600, 700, 800, 900, 1000, 1500, 2000, 2500, 5000, 10000, 50000, 100000, 500000 nm, or any other appropriate overall diameter. In various embodiments, the ratio of the thicknesses or diameters of core fiber and HTS reinforcing material are 1:100, 1:50, 1:20, 1:10, 1:5, 1:4, 1:3, 1:2, 1:1, 2:1, 3:1, 4:1, 5:1, 10:1, 20:1, 50:1, 100:1, or any other appropriate ratio.

### Single Direction Melt Growth (SDMG) to Make Reinforced HTS

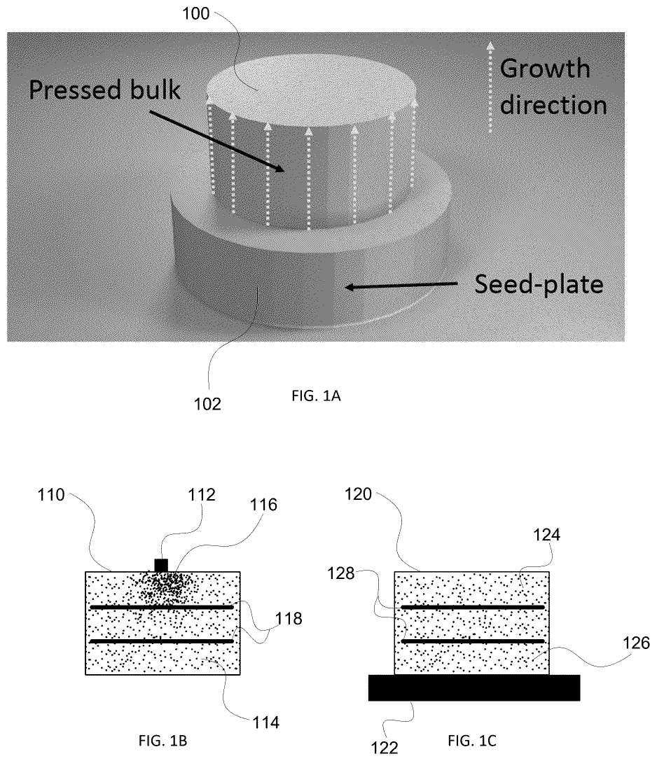

FIG. 1A is a diagram illustrating an embodiment of a process for a reinforced HTS material. In the example shown, a Single Direction Melt Growth (SDMG) method uses broad, flat single crystal seed-plate 102 to initiate single crystal growth in block 100 of compressed HTS component powders (e.g., a pressed block of powders with fiber layers). Broad, flat single crystal seed-plate 102 surface area is larger than block 100. Single growth is upward along a flat plane from the broad, flat single crystal seed-plate 102 surface.

A flat crystal growth plane causes much less crystal growth disruption from fibers placed parallel to the growth plane than the SDMG rounded growth plane. Less disruption allows more reinforcement fiber in a given reinforced HTS sample raising fiber density and improving reinforced HTS strength.

FIG. 1B is a diagram illustrating an embodiment of a cross section of a reinforced HTS material. In some embodiments, reinforced HTS material 110 comprises a typical top seed material cross section in contrast to plate seed or single direction melt growth seed produced material. In the example shown, reinforced HTS material 110 is shown in a cross-section view that was annealed in contact with top seed 112. Reinforced HTS material 110 includes fibers 118 annealed into and as reinforcement for reinforced HTS material 110. In various embodiments, fibers 128 are placed in multiple layers, in multiple directions in the layers, are placed substantially from one side of the material to the other side of the material, are spiraled, are hooped, are placed in three dimensional structures, or any other appropriate configuration for reinforcement. As a result of the crystallization being seeded from top seed 112, reinforced HTS material 110 is not homogeneous and can be inspected to see features that are more dense in region 116 near to top seed 112 and features that are less dense in region 114.

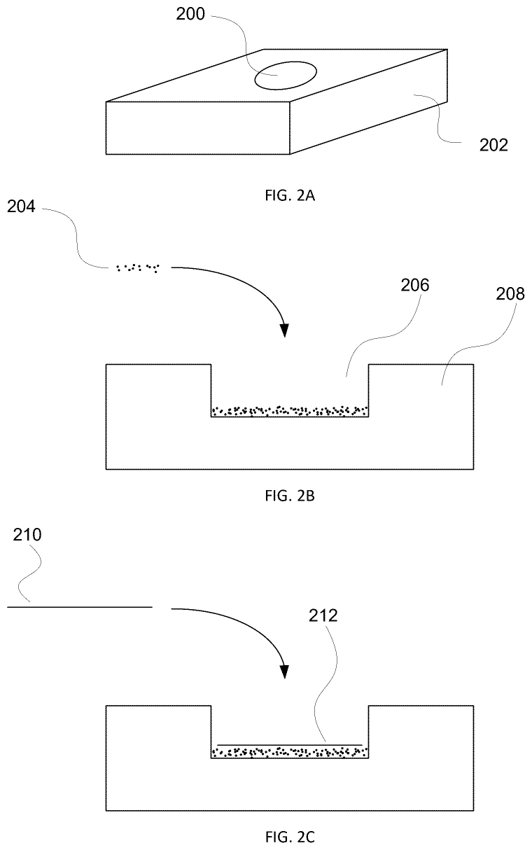

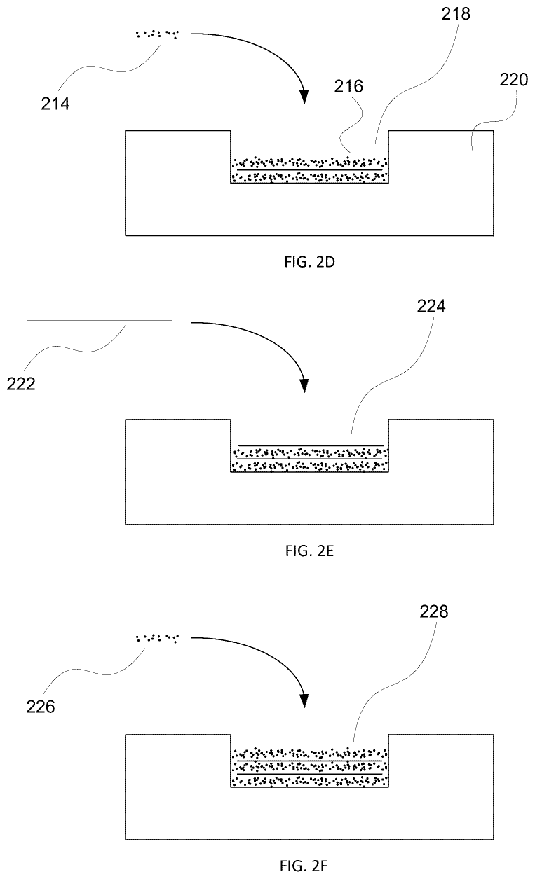

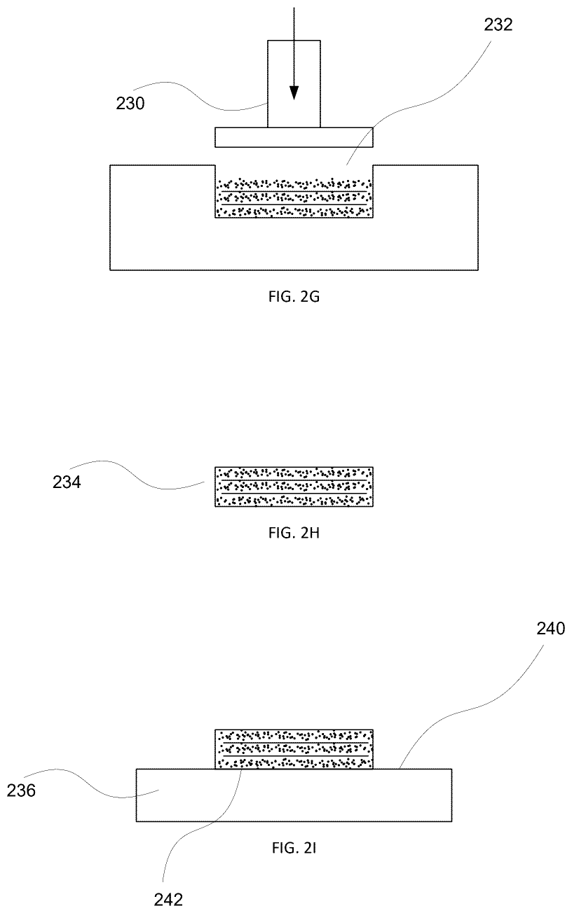

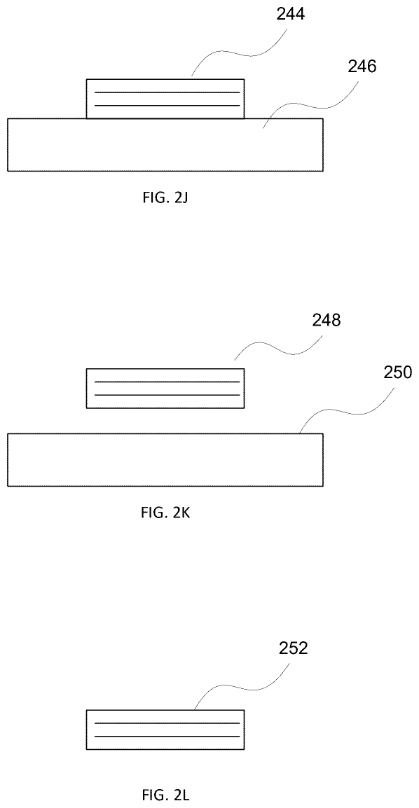

FIG. 1C is a diagram illustrating an embodiment of a cross section of a reinforced HTS material. In some embodiments, reinforced HTS material 120 comprises a plate seed material cross section similar to plate seed or single direction melt growth seed produced material of FIG. 1A and FIGS. 2A-2L. In the example shown, reinforced HTS material 120 is shown in a cross-section view that was annealed in contact with plate seed 122. Reinforced HTS material 120 includes fibers 128 annealed into and as reinforcement for reinforced HTS material 120. In various embodiments, fibers 128 are placed in multiple layers, in multiple directions in the layers, are placed substantially from one side of the material to the other side of the material, are spiraled, are hooped, are placed in three dimensional structures, or any other appropriate configuration for reinforcement. As a result of the crystallization being seeded from plate seed 122, reinforced HTS material 120 is substantially homogeneous and can be inspected to see features that are similarly dense in region 126 near to plate seed 122 and in region 124.

FIGS. 2A-2L are block diagrams illustrating an embodiment of a process for a reinforced HTS material. In some embodiments, the process of FIGS. 2A-2L are used for the process of FIG. 1A. In the example shown, for mold cavity 200 of mold 202 in FIG. 2A a cut view is shown in FIG. 2B (e.g., mold cavity 206 in mold 208). In fiber reinforced SDMG, HTS Component Powders are pulverized and mixed with a preforming powder to form HTS constituent materials 204. In some embodiments, the HTS Component Powders are REBa₂Cu₃O₇₋ₓ. In some embodiments, the preforming powder is RE₂BaCuO₅. In various embodiments, RE comprises one or more Rare Earth Elements (e.g., yittrium (Y), gadolinium (Gd), europium (Eu), etc.). The resultant mix powder (e.g., HTS constituent materials 204) is then sprinkled into a mold in a layer (e.g., added to mold cavity 206 of mold 208) to form a layer with a material plane (e.g., the top of the HTS constituent materials forms a substantially flat surface within mold cavity 206 of mold 208). Reinforcement fiber 210 in FIG. 2C is placed on the surface of the layer with reinforcement fiber 210 being parallel to the layer surface (e.g., placed as depicted at 212 in FIG. 2C). In FIG. 2D, another layer of mix powder 214 is sprinkled in mold cavity 218 of mold 220 on the previously placed fiber (e.g., at 216 in FIG. 2D). These steps are repeated until the mold is filled (e.g., adding fiber 222 of FIG. 2E into mold cavity 224 of FIG. 2E and adding mix powder 226 of FIG. 2F into mold cavity 228 of FIG. 2F). The mixed powder with reinforcement fiber 232 of FIG. 2G is then compressed into a block (e.g., using piston 230 of FIG. 2G that pushes into the mold cavity) and taken out of the mold. Free standing block 234 of FIG. 2H maintains its shape and integrity without the mold and is placed on seed-plate 236 of FIG. 2I where a flat surface of freestanding block 242 is placed on a flat surface of seed-plate 240

The free standing block is sintered at high temperature (e.g., block 244 in contact with seed-plate 246 of FIG. 2J are heated to a high temperature in an oven), which a) pushes air out of the block, and b) causes component powders to melt (e.g., to form into a single material crystal). The block (e.g., block 244) shrinks in size due to the release of air, but retains its free standing structural integrity due to the preforming powder. In some embodiments, block 244 is annealed by placing it on the single seed crystal plate (e.g., seed-place 246 of FIG. 2J) and heating to a higher temperature to fully melt component powders into a liquid phase within a solid matrix of preforming powder. The block is then cooled under oxygen to trigger single crystal formation beginning at its bottom where it contacts the single seed crystal plate. Single crystal continues to grow from the bottom up until the top of the block. The now single crystal, fiber reinforced HTS block is then cooled to room temperature and separated from the single seed crystal plate for storage and transport (e.g., single crystal block 248 and seed-plate 250 are separated from each other in FIG. 2K to allow single crystal block 252 of FIG. 2L to be provided for storage and transport).

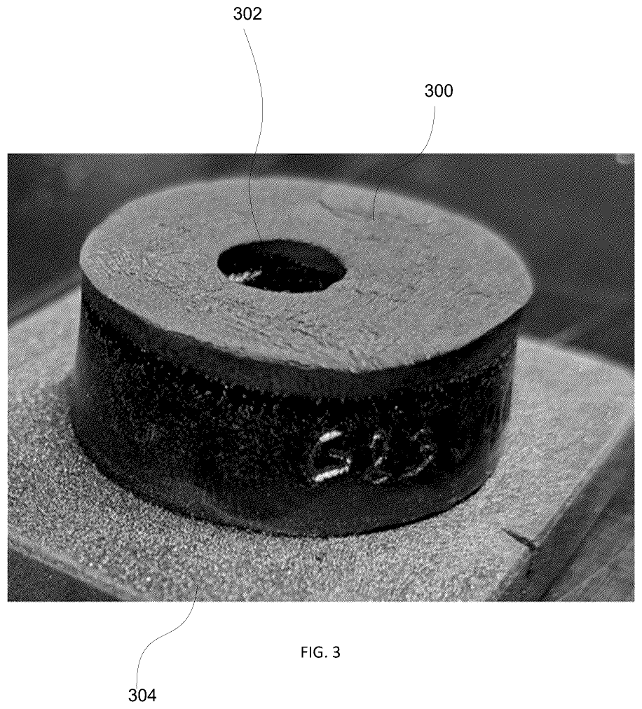

FIG. 3 is a diagram illustrating an embodiment of a reinforced HTS material. In some embodiments, HTS block 300 of FIG. 3 comprises a variation of block 100 of FIG. 1. In the example shown, SDMG 304 can be used to grow hollow, single crystal HTS blocks (e.g., HTS block 300 in a cylinder shape with hollow cylinder core 302) by using a compressed HTS component powder block in with a hollow core. In some embodiments, an HTS block will have a round cross section to form a reinforced HTS cylinder with no hollow core (e.g., as shown in FIG. 1).

Making Reinforcement Fiber Hoops and Spirals from Straight Fiber Using Collars

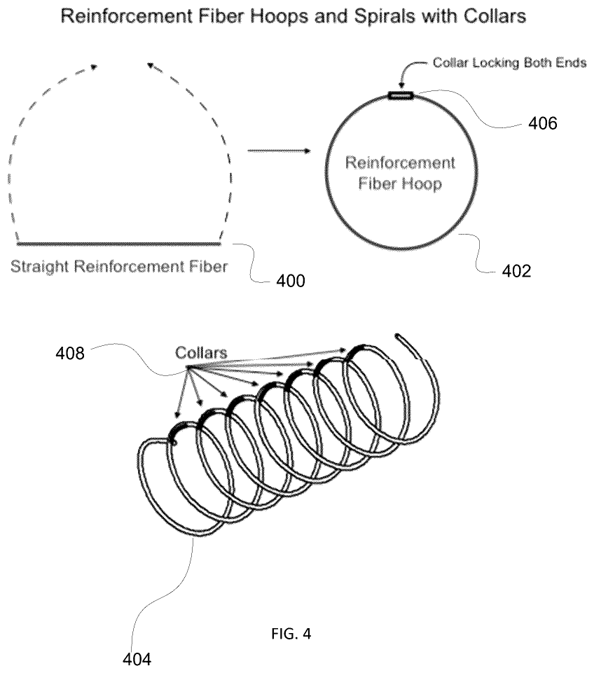

FIG. 4 is a diagram illustrating an embodiment of fibers of a set of fibers for reinforcement of an HTS material. In some embodiments, the fibers of FIG. 4 are used in reinforcement of HTS materials in FIG. 1, FIGS. 2A-2L, and FIG. 3. In the example shown, spiral reinforcement fibers 404 and hoops 402 can be made by joining sections of straight reinforcement fiber 400 using a collar (e.g., collar 406 and collars 408) whose material dissolves when HTS component powders are heated to form HTS crystal. After the collar dissolves, the fiber is held in hoop or spiral form by the HTS crystal matrix. In some embodiments, this collar material is silver (Ag) (e.g., the collar is made from silver and is designed to hold ends of fiber material in place—for example, by being a hollow cylinder that is compressed around two ends of fibers that are, after compression, then joined mechanically by the collar). The circular reinforcement fiber hoops and spirals can be used to provide strength against radial stresses as incurred in superconductor solenoids, Superconducting Fault Current Limiters, and bulk superconductors.

### Superconductor Solenoids Using Reinforced HTS Process I: Reinforced Wafers

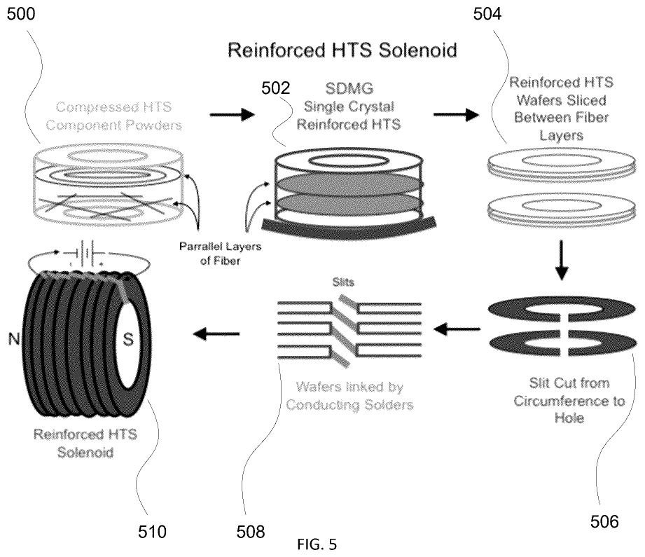

FIG. 5 are diagrams illustrating a process for a reinforced HTS solenoids. In some embodiments, the process of FIG. 5 is similar to a process of FIGS. 2A-L. In the example shown, a reinforced HTS solenoid can be made by:
1) reinforcing SDMG HTS blocks with horizontal planes of fiber (e.g., HTS single crystal block 502 made from compressed block 500 using a process similar to the process depicted in FIGS. 2A-L). In various embodiments, fiber planes are made with hoop reinforcement fibers, spiral reinforcement fibers, straight reinforcement fibers, or any combination thereof.
2) Growing (e.g., forming using a mold) or drilling a central bore hole in the reinforced HTS block perpendicular to the fiber planes. In some embodiments, the reinforced HTS block can be made with compressed HTS component powder block with a hollow core already formed (e.g., formed by having a mold with a central bore shaped in the mold). In some embodiments, the compressed HTS component powder block with a hollow core will have a round cross section forming a cylinder
3) Slicing the block between fiber reinforcement planes into thin wafers (e.g., thin wafer 504 is created by cutting a HTS single crystal block between layers of the fiber reinforcement after the HTS compressed block is annealed to create a reinforced wafer(s)).
4) Cutting a slit in each reinforced HTS wafer (e.g., wafer 506) from its circumference to its central hole.
5) Linking wafers into solenoid stack 508 by soldering (e.g., joining an end of one wafer to an end of another wafer using an electrically conductive material) an open slit cut from one wafer to the opposite open slit cut of the next wafer with conductive metal. In some embodiments, this soldered link is comprised of a metal (e.g., silver (Ag)). The conductive metal enables passing electric current from one wafer to the next enabling the wafers to collectively create a solenoid. The wafers are insulated from each other (except for the electric current conduction metal) with electrical insulation which separates one wafer from the next. In some embodiments, this electric insulation is air. In some embodiments, the insulation is composed partly or in whole of structurally sound filler which gives strength and resilience to the solenoid. In some embodiments, when a current is passed through the solenoid stack in superconducting mode, the solenoid stack comprises an electromagnet (e.g., electromagnet 510).

### Superconductor Solenoids Using Reinforced HTS Process II: Reinforced Spiral

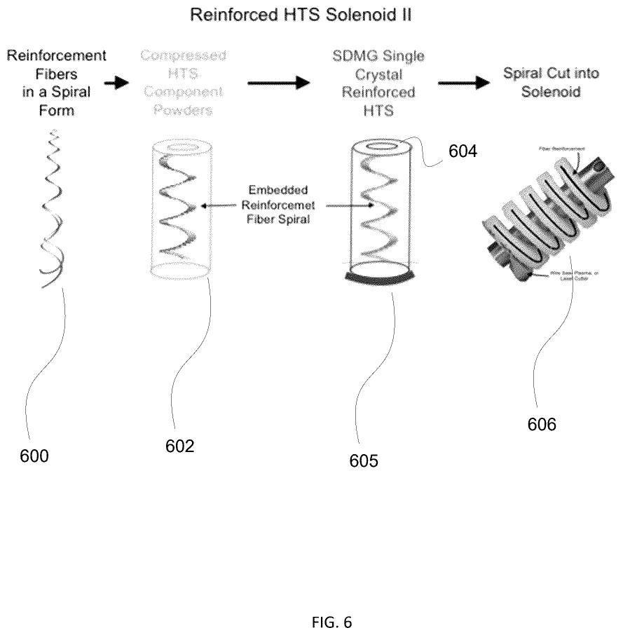

FIG. 6 are diagrams illustrating a process for a reinforced HTS solenoids. In some embodiments, the process of FIG. 6 is similar to a process of FIGS. 2A-L. In the example shown, a reinforced HTS solenoid can be made by:
1) reinforcing SDMG HTS blocks with concentric fiber spirals (e.g., spiral fibers 600) such that the fibers are coordinated and collectively form a corkscrew form, single spiral tape plane within the block (e.g., spiral fibers form parallel fibers of a tape plane within HTS compressed block 602). Fiber spirals have a) the same handedness (either right or left), b) the same pitch (turns per vertical distance), but c) varying diameter. A multi-fiber reinforcement form is made by configuring the spiral fiber columns along the same axis with the lowest diameter spiral in the center followed circumferentially by succeedingly larger diameter fibers. Individual fibers are rotated until their pitches are synchronized to form a corkscrew. Use the fiber form to produce a reinforced HTS cylinder by either cylinder SDMG or boring of a central hole in solid SDMG samples. In some embodiments, the corkscrew form's spiral plane can contain straight fibers and/or hooped fibers, or any combination thereof.
2) The spiral fiber is held in place by a vertical frame jig in a vertical, open topped mold. In some embodiments, the jig is made of thin silver wire. In some embodiments, multiple spiral fiber and jigs can be placed one on top of each other in a vertical mold to increase height. Mixed component and preforming powder is poured into the top of the mold around the spiral fiber and jig. The mixed powder with reinforcement fiber is then compressed into a block and taken out of the mold. The free standing block maintains its shape and integrity without the mold.
3) The free standing block is sintered at high temperature a) pushing air out of the block, and b) causing component powders to melt into liquid. The block shrinks in size due to the release of air, but retains its free standing structural integrity due to the preforming powder.
4) The block (e.g., block 604) is annealed by placing it on the single seed crystal plate (e.g., plate 605) and heating to a higher temperature to fully melt component powders into a liquid phase within a solid matrix of preforming powder. The block is then cooled under oxygen to trigger single crystal formation beginning at its bottom where it contacts the single seed crystal plate. Single crystal continues to grow from the bottom up until the top of the block. The now single crystal, fiber reinforced HTS block is then cooled to room temperature for storage and transport.
5) Use the fiber form to produce a reinforced HTS cylinder by either cylinder SDMG or boring of a central hole in solid SDMG samples. Grow or drill a central bore hole in the reinforced HTS block perpendicular to the fiber planes. In some embodiments, the reinforced HTS block can be grown with compressed HTS component powder block with a hollow core already formed. In some embodiments, the compressed HTS component powder block with a hollow core will have a round cross section forming a cylinder which will be subsequently annealed into solid HTS crystal.
6) Slice the Reinforced HTS block continuously along the corkscrew form's spiral plane (the Pineapple Cut) to form HTS solenoid (e.g., solenoid 606). The solenoid winds can be separated by a structural insulation material to provide electrical insulation and strength 5) above. In some embodiments, the insulation can be air.
7) In some embodiments, the SDMG Single Crystal Reinforced HTS shown below is grown with a tilted seed crystal axis such the Reinforced HTS crystal a-b conduction plane grows perpendicular to the solenoid axis.

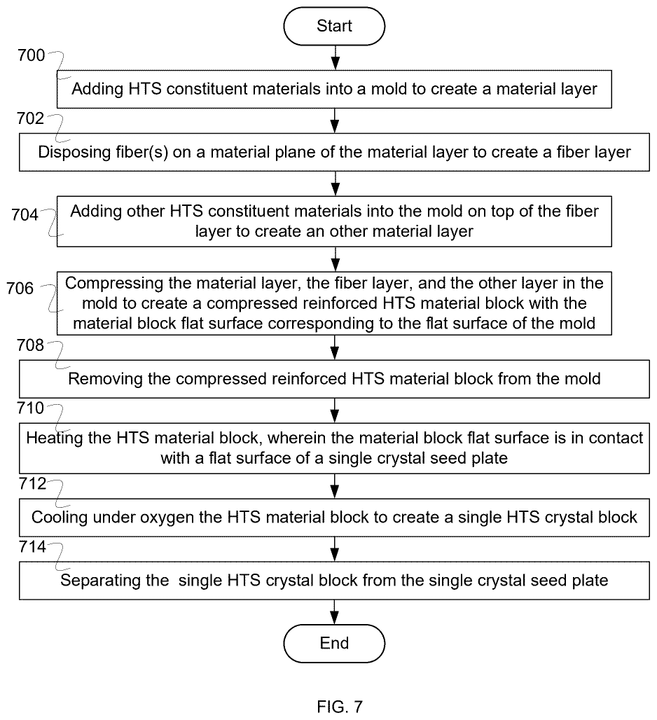

FIG. 7 is a flow diagram illustrating an embodiment of a process for a reinforced HTS material. In some embodiments, the process of FIG. 7 is used to create the reinforced HTS material in FIG. 1A, FIG. 1C, and FIGS. 2A-2L. In the example shown, in 700 HTS constituent materials are added into a mold to create a material layer. In 702, fiber(s) are disposed on a material plane of the material layer to create a fiber layer. In 704, other HTS constituent materials are added into the mold on top of the fiber layer to create an other material layer. In some embodiments, steps 702 and 704 are repeated to create a multiple fiber layer reinforced HTS material. In some embodiments, a complex fiber structure is placed in the mold and HTS constituent materials are added after (e.g., not a layer by layer process). In 706, the material layer, the fiber layer, and the other layer in the mold are compressed to create a compressed reinforced HTS material block with the material block flat surface corresponding to the flat surface of the mold. In 708, the compressed reinforced HTS material block is removed from the mold. In 710, the HTS material block is heated, where the material block flat surface is in contact with a flat surface of a single crystal seed plate. In 712, under oxygen, the HTS material block is cooled to create a single HTS crystal block. In 714, the single HTS crystal block is separated from the single crystal seed plate.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A method, comprising:
adding HTS constituent materials into a mold to create a material layer, wherein the material layer comprises a material plane substantially parallel to a flat surface of the mold;
disposing a set of fibers that extend approximately from one edge of the mold to approximately another edge of the mold on the material plane of the material layer to create a fiber layer;
adding other HTS constituent materials into the mold on top of the fiber layer to create an other material layer;
compressing the material layer, the fiber layer, and the other layer in the mold to create a compressed reinforced HTS material block with a material block flat surface corresponding to the flat surface of the mold;
removing the compressed reinforced HTS material block from the mold;
heating the compressed reinforced HTS material block, wherein the material block flat is surface is in contact with a flat surface of a single crystal seed plate;
cooling under oxygen the HTS material block to create a single HTS crystal block; and
separating the single HTS crystal block from the single crystal seed plate.

2. The method as in claim 1, wherein the HTS constituent materials comprise materials for a HTS superconductor comprising: a ceramic material, a copper oxide material, a rare earth copper oxide material (RE)BCO (e.g., (RE)Ba₂Cu₃O₇), an iron arsenide material, an iron selenide material, a LaBaCuO material, a LaSrCuO material, a LaSrCaCuO material, a YBaCuO material, a BiSrCaCuO material, a TiBaCaCuO material, a HgBACaCuO material, a HgTiBaCaCuO material, a LnFeAs(O,F) material, a (Ba, K, Li, Na)FeAs material, a FeSe material, a MgB material, a BKBO material, a RbCsC material, a YbPdBC material, a NbGe material, wherein RE stands for a rare earth element, where the rare earth elements include cerium (Ce), dysprosium (Dy), erbium (Er), europium (Eu), gadolinium (Gd), holmium (Ho), lanthanum (La), lutetium (Lu), neodymium (Nd), praseodymium (Pr), promethium (Pm), samarium (Sm), scandium (Sc), terbium (Tb), thulium (Tm), ytterbium (Yb), and yttrium (Y).

3. The method of claim 1, wherein a fiber of the set of fibers comprises a fiber with a high melting point and a fiber that forms a durable oxide.

4. The method of claim 1, wherein a fiber of the set of fibers comprises SiC fiber.

5. The method of claim 1, wherein a fiber of the set of fibers comprise one or more of Silicon (Si), Silicon Nitride (Si₃N₄), Silicates including Silicon Dioxide (SiO₂), Boron (B), Boron Carbide (B₄C), Boron Nitride (BN), Chromium (Cr), Chromium Carbides (Cr₃C₂, Cr₇C₃, Cr₂₃C₆), Chromium Nitrides (CrN, Cr₂N), Hafnium Carbide (HfC), Zirconium Carbide (ZrC), Zirconium Nitride (ZrN), Zirconium Diboride (ZrB₂), Titanium (Ti), Titanium Carbide (TiC), Titanium nitride (TiN), Tungsten Carbide (WC), Aluminum (Al), Alumina (Al₂O₃), Aluminum Carbide (Al₄C₃), Aluminum Nitride (AlN), Titanium Aluminum Nitride (TiAlN), Aluminum Titanium Nitride (AlTiN) fiber.

6. The method of claim 1, wherein a fiber of the set of fibers comprises a core of metal and a SiC outside the core.

7. The method of claim 1, wherein the compressed reinforced HTS block comprises a cylinder shape.

8. The method of claim 1, wherein the compressed reinforced HTS block comprises a is cylinder shape with a hollow core.

9. The method of claim 1, wherein a fiber of the set of fibers comprises a fiber hoop with a collar used to form the fiber hoop.

10. The method of claim 1, wherein a fiber of the set of fibers comprises a fiber spiral with a set of collars used to form the fiber spiral.

11. The method of claim 1, wherein the single crystal HTS block comprises a central bore hole.

12. The method of claim 11, wherein the central bore hole is formed using the mold.

13. The method of claim 11, wherein the central bore hole is formed by drilling.

14. The method of claim 11, further comprising slicing the single crystal HTS block between fiber layer of the single crystal HTS block to create a plurality of reinforced wafers.

15. The method of claim 14, wherein slits are cut in each of the plurality of reinforced wafers.

16. The method of claim 15, wherein an end of a slit of a wafer of the plurality of reinforced wafers is soldered to an other end of an other slice of an other wafer of the plurality of wafers to create a solenoid.

17. The method of claim 11, further comprising spiral cutting the single crystal HTS block between fiber spirals of the single crystal HTS block to create a solenoid.

18. A device, comprising:
a single HTS crystal block, wherein the single HTS crystal block was created by:
adding HTS constituent materials into a mold to create a material layer, wherein the material layer comprises a material plane substantially parallel to a flat surface of the mold;
disposing a set of fibers that extend approximately from one edge of the mold to approximately another edge of the mold on the material plane of the material layer to create a fiber layer;
adding other HTS constituent materials into the mold on top of the fiber layer to create an other material layer;
compressing the material layer, the fiber layer, and the other layer in the mold to create a compressed reinforced HTS material block with a material block flat surface corresponding to the flat surface of the mold;
removing the compressed reinforced HTS material block from the mold;
heating the compressed reinforced HTS material block, wherein the material block flat surface is in contact with a flat surface of a single crystal seed plate;
cooling under oxygen the HTS material block to create the single HTS crystal block; and
separating the single HTS crystal block from the single crystal seed plate.

19. A device of claim 18, further comprising a central bore hole, and wherein the single crystal HTS block is sliced between fiber layer of the single crystal HTS block to create a plurality of reinforced wafers, wherein slits are cut in each of the plurality of reinforced wafers, and wherein an end of a slit of a wafer of the plurality of reinforced wafers is soldered to an other end of an other slice of an other wafer of the plurality of wafers to create a solenoid.

20. A device of claim 18, further comprising a central bore hole, and wherein spiral cutting the single crystal HTS block between fiber spirals of the single crystal HTS block creates a solenoid.
